(19) United States
(12) Patent Application Publication
(10) Pub. No.: US 2006/0148113 A1
(43) Pub. Date: Jul. 6, 2006

(54) Chain resistance pattern and method of forming the same

(75) Inventor: Myung Jin Jung, Gwanak-gu (KR)

Correspondence Address: MCKENNA LONG & ALDRIDGE LLP, 1900 K STREET, NW, WASHINGTON, DC, 20006, US

(73) Assignee: DongbuAnam Semiconductor Inc., Seoul (KR)

(21) Appl. No.: 11/319,589

(22) Filed: Dec. 29, 2005

(30) Foreign Application Priority Data
Dec. 30, 2004 (KR) 10-2004-0116636

(51) Int. Cl. H01L 21/66; G01R 31/26

(52) U.S. Cl. 438/17

(57) ABSTRACT

A chain resistance pattern and a method of forming the same enable a test pattern to obtain maximum measurement results using minimum area and enable accurate detection of process errors. The chain resistance pattern includes an active layer for receiving an externally applied optical signal, a plurality of conductive layers sequentially stacked on the active layer to form a layer stack, a plurality of contacts, formed between each layer of the layer stack, to electrically connect each pair of adjacently disposed layers of the layer stack, and a pad connected to each layer of the layer stack.

This application claims the benefit of Korean Patent Application No. 10-2004-0116636, filed on Dec. 30, 2004, which is hereby incorporated by reference for all purposes as if fully set forth herein.

### BACKGROUND OF THE INVENTION

1. Field of the Invention

The present invention relates to semiconductor devices, and more particularly, to a chain resistance pattern and a method of forming the same, which enables an improved test pattern to obtain maximum measurement results using minimum layout area and which enables accurate detection of process errors.

2. Discussion of the Related Art

In the field of semiconductor device manufacture, in-process tests are performed to measure various resistances using test patterns. The test patterns of the related art for contact resistance measurement are based on a chain resistance or a Kelvin resistance. A contact chain resistance pattern obtains an actual resistance value by measuring a sample device, e.g., a unit under test, and is used in monitoring proper process execution. A Kelvin resistance, on the other hand, is a theoretical contact resistance. Therefore, the use of contact chain resistance patterns is necessary for application in scribe lanes. Scribe lanes are wafer regions reserved for chip sawing.

Confirming the contact chain resistances of each of six conductive layers, however, requires six contact patterns or chains. Additionally, six other test patterns are required for confirming the respective stack chain resistances of the conductive layers. The measurements also require 24 terminals and corresponding pads. It is difficult to locate these various components, including both the contact chain resistance and the stack chain resistance, in the scribe lanes of a wafer. Thus, process parameters have been measured and monitored by assigning other process level test-element-group (TEG) areas. Specifically, with the advent of nano-processing in the manufacture of semiconductor devices, it is desirable to devise a contact chain resistance pattern and a stack chain resistance pattern for placement and use in the scribe lanes of a wafer.

### SUMMARY OF THE INVENTION

Accordingly, the present invention is directed to a chain resistance pattern and method of forming the same that substantially obviates one or more problems due to limitations and disadvantages of the related art.

An advantage of the present invention is to provide a chain resistance pattern and a method of forming the same, which enables a test pattern to obtain maximum measurement results using minimum area.

Another advantage of the present invention is to provide a chain resistance pattern and a method of forming the same, which enables accurate detection of process errors.

An advantage of the present invention is to provide a chain resistance pattern and a method of forming the same, which locates a test pattern in a scribe lane, from which all chain resistances can be measured, by forming a unified chain resistance pattern for measuring a contact resistance.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the invention, as embodied and broadly described, a chain resistance pattern includes an active layer for receiving an externally applied optical signal, a plurality of conductive layers sequentially stacked on said active layer to form a layer stack, a plurality of contacts, formed between each layer of the layer stack, to electrically connect each pair of adjacently disposed layers of the layer stack, and a pad connected to each layer of the layer stack.

According to another aspect of the present invention, a method of forming a chain resistance pattern includes stacking a plurality of metal layers on an active layer to form a layer stack, connecting each pair of adjacently disposed layers of the layer stack using a plurality of contacts, connecting a pad to a terminal of each layer of the layer stack, forming a chain resistance pattern on each metal layer, and calculating a chain resistance for each metal layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principle of the invention. In the drawings:

FIG. 1 is a schematic diagram of a test pattern including a chain resistance pattern according to an exemplary embodiment of the present invention; and

FIG. 2 is a flowchart of a method of forming the test pattern including the chain resistance pattern according to an exemplary embodiment of the present invention.

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

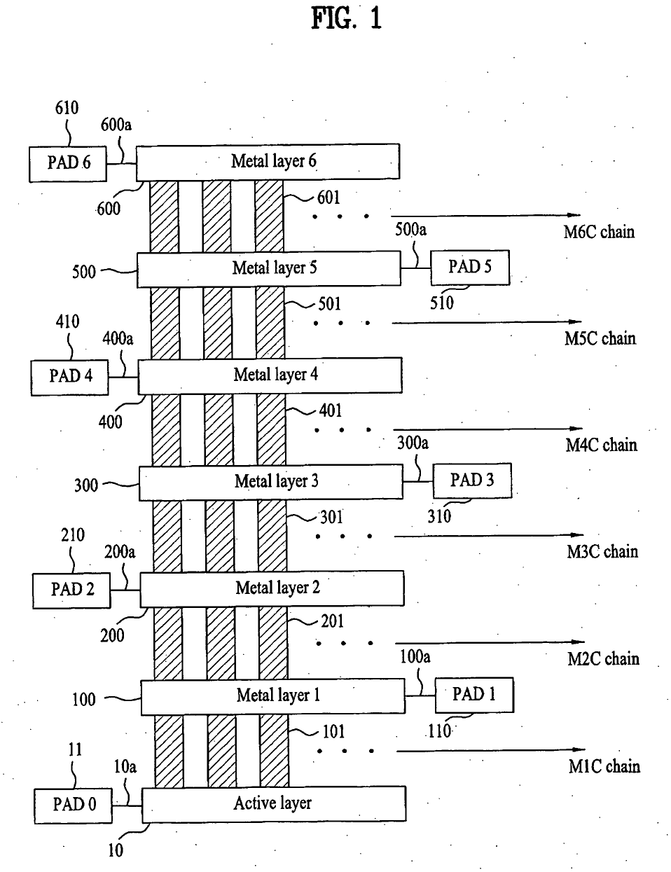

Referring to FIG. 1, a test pattern including a chain resistance pattern according to an embodiment of the present invention includes a layer stack formed by six conductive layers 100, 200, 300, 400, 500, and 600. The conductive layers are sequentially stacked on an active layer 10, which may be a gate layer, for receiving an externally applied optical signal, and a set of pads 11, 110, 210, 310, 410, 510, and 610 connected to terminals 10a, 100a, 200a, 300a, 400a, 500a, and 600a of the active layer and the six conductive layers, respectively. The conductive layers may be formed of a low-resistance metal. Also, the terminals may be provided at alternating sides of the chain resistance pattern, so that the terminals, and their corresponding pads, of each pair of adjacently disposed layers are located on opposite sides of the chain resistance pattern.

A plurality of contacts is provided for electrically connecting the active layer 10 and first conductive layer 100, and for similarly connecting each pair of adjacently disposed layers formed in succession. That is, a plurality of contacts 101 connects points of the first conductive layer 100 to corresponding points of the active layer 10, a plurality of contacts 201 connects points of the second conductive layer 200 to corresponding points of the first conductive layer 100, a plurality of contacts 301 connects points of the third conductive layer 300 to corresponding points of the second conductive layer 200, a plurality of contacts 401 connects points of the fourth conductive layer 400 to corresponding points of the third conductive layer 300, a plurality of contacts 501 connects points of the fifth conductive layer 500 to corresponding points of the fourth conductive layer 400, and a plurality of contacts 601 connects points of the sixth conductive layer 600 to corresponding points of the fifth conductive layer 500. Then, a chain resistance pattern is formed on each of the first through sixth conductive layers 100 to 600. A contact chain resistance or a stack chain resistance using seven terminals, if a layer stack having exactly six conductive layers is employed, is thereby obtained. The layer stack may be formed of any number of conductive layers sequentially stacked on the active layer 10.

In the related art, when a plurality of conductive layers are provided in a predetermined area, test patterns, corresponding to each conductive layer, are created in the same area. For example, if six metal layers are provided in a predetermined area, a set of test patterns M1C, M2C, M3C, M4C, M5C, and M6C, corresponding to each of the metal layers, is created in the same area. On the other hand, in an exemplary embodiment of the present invention, all the contact chain resistances and the stack chain resistances can be measured with a single test pattern. Therefore, a scribe lane can be efficiently utilized, and assignment of areas to a particular process level TEG becomes unnecessary. In addition, throughput during process control monitor (PCM) measurement can be greatly improved.

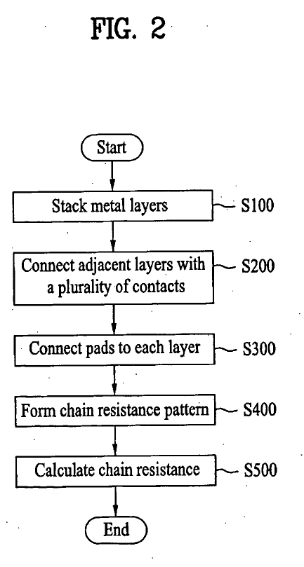

FIG. 2 illustrates a method of forming the test pattern including the chain resistance pattern according to an embodiment of the present invention. As shown in FIG. 2, a plurality of conductive layers may be sequentially stacked on an active layer (S100). A layer stack may be formed in which each layer is provided with a separate terminal. A plurality of contacts may be formed between each layer of the layer stack, to electrically connect each pair of adjacently disposed layers of the layer stack (S200). A pad may be connected to each of the terminals (S300). A chain resistance pattern may be formed on each conductive layer (S400). A chain resistance may be calculated for each conductive layer (S500). Therefore, the calculated chain resistance may be associated with a specific layer or a specific stack of layers.

It will be apparent to those skilled in the art that various modifications and variations can be made in the present invention without departing from the spirit or scope of the invention. Thus, it is intended that the present invention cover the modifications and variations provided they come within the scope of the appended claims and their equivalents.

What is claimed is:

1. A chain resistance pattern, comprising:
an active layer for receiving an externally applied optical signal;
a plurality of conductive layers sequentially stacked on said active layer to form a layer stack;
a plurality of contacts, formed between each layer of the layer stack, to electrically connect each pair of adjacently disposed layers of the layer stack; and
a pad connected to each layer of the layer stack.

2. The chain resistance pattern according to claim 1, wherein said plurality of contacts electrically connect corresponding points of each pair of adjacently disposed layers of the layer stack.

3. The chain resistance pattern according to claim 1, wherein each layer of the layer stack is provided with a separate terminal and wherein said pad is connected to the separate terminal of each layer.

4. The chain resistance pattern according to claim 3, wherein separate terminals of each pair of adjacently disposed layers of the layer stack are provided at alternating sides of the chain resistance pattern, such that the pads of each pair of adjacently disposed layers of the layer stack are located on opposite sides of the chain resistance pattern.

5. The chain resistance pattern according to claim 1, wherein the conductive layers are each formed of a low-resistance metal.

6. A method of forming a chain resistance pattern, comprising:
stacking a plurality of metal layers on an active layer to form a layer stack;
connecting each pair of adjacently disposed layers of the layer stack using a plurality of contacts;
connecting a pad to a terminal of each layer of the layer stack;
forming a chain resistance pattern on each metal layer; and
calculating a chain resistance for each metal layer.

7. The method according to claim 6, wherein calculating a chain resistance comprises calculating a contact chain resistance.

8. The method according to claim 6, wherein calculating a chain resistance comprises calculating a stack chain resistance.
